(19) United States
(12) Patent Application Publication
(10) Pub. No.: US 2026/0198146 A1
(43) Pub. Date: Jul. 9, 2026

(54) DISPLAY PANEL AND DISPLAY DEVICE

(71) Applicant: BOE Technology Group Co., Ltd., Beijing (CN)

(72) Inventors: Yingtao WANG, Beijing (CN); Tingting ZHOU, Beijing (CN); Xuefei SUN, Beijing (CN); Haokun LI, Beijing (CN); Jaegeon YOU, Beijing (CN)

(21) Appl. No.: 18/862,290

(22) PCT Filed: Oct. 26, 2023
(86) PCT No.: PCT/CN2023/126792

§ 371 Date: Nov. 1, 2024

(51) Int. Cl. H10H 20/851; H10H 20/814; H10H 20/841; H10H 20/856; H10H 29/32; H10H 29/45; H10H 29/85

(52) U.S. Cl. CPC H10H 20/8515; H10H 20/841; H10H 20/856; H10H 29/32; H10H 29/8508; H10H 29/8517; H10H 20/814; H10H 29/45

(57) ABSTRACT

Disclosed are a display panel and a display device, the display panel includes: a plurality of reflective structures; a plurality of quantum dot structures on a side of the plurality of reflective structures; and a plurality of blue light diodes on a side of the plurality of quantum dot structures facing away from the plurality of reflective structures, where the blue light diodes emit blue light at least towards corresponding reflective structures.

### CROSS-REFERENCE TO RELATED APPLICATIONS

The application is a National Stage of International Application No. PCT/CN2023/126792, filed Oct. 26, 2023, which is hereby incorporated by reference in its entirety.

### TECHNICAL FIELD

The present disclosure relates to the technical field of display, and in particular to a display panel and a display device.

### BACKGROUND

LED based quantum dot display products are usually transmissive quantum dot displays, which can emit pure red and green light by exciting quantum dots with blue light.

However, since quantum dots cannot completely absorb blue light, it is necessary to increase the color film on the light emitting side of the display product to absorb blue light, which results in a lower utilization rate of blue light.

### SUMMARY

Embodiments of the present disclosure provide a display panel and a display device for solving a technical problem of low blue light absorption rate of a quantum dot-based display product existing in the related art.

In a first aspect, to solve the above technical problem, embodiments of the present disclosure provide a display panel including:
a plurality of reflective structures;
a plurality of quantum dot structures on a side of the plurality of reflective structures; and
a plurality of blue light diodes on a side of the plurality of quantum dot structures facing away from the plurality of reflective structures, where the blue light diodes emit blue light at least towards corresponding reflective structures.

In some embodiments, the display panel further includes: a first substrate and a second substrate arranged in a box alignment manner;
where the first substrate is bonded to the second substrate by a transparent adhesive; the plurality of reflective structures and the plurality of quantum dot structures are on the first substrate;
the plurality of blue light diodes are on the second substrate.

In some embodiments, the first substrate further includes a first base substrate;
the first base substrate is provided with a plurality of grooves on a side facing the second substrate;
the reflective structures are on inner surfaces of the grooves, and the quantum dot structures fill up corresponding grooves.

In some embodiments, the second substrate further includes:
a second base substrate;
a plurality of groups of color filters on a surface of the second base substrate;
where each group of color filters includes a red color filter and a green color filter; the red color filter corresponds to a quantum dot structure emitting red light, and the green color filter corresponds to a quantum dot structure emitting green light.

In some embodiments, the grooves include:
a plurality of primary grooves arranged in a first direction and at least one secondary groove arranged between two adjacent primary grooves;
where the reflective structures include:
a plurality of primary reflective structures arranged in the first direction and at least one secondary reflective structure arranged between two adjacent primary reflective structures;
where the primary reflective structures are on inner surfaces of the primary grooves and the secondary reflective structure are on an inner surface of the secondary groove;
the primary reflective structure corresponds to one blue light diode, the at least one secondary reflective structure is located between two adjacent primary reflective structures; a longitudinal cross-sectional area of the secondary reflective structure is smaller than a longitudinal cross-sectional area of the primary reflective structure;
the quantum dot structures include a hybrid material of red light emitting quantum dots and green light emitting quantum dots.

In some embodiments, the display panel further includes: a first substrate;
where the plurality of reflective structures, the plurality of quantum dot structures, and the plurality of blue light diodes are on the first substrate.

In some embodiments, the first substrate further includes:
a first base substrate;
a plurality of driving circuits on a side of the first base substrate; where the plurality of driving circuits correspond one-to-one with the plurality of blue light diodes, the driving circuits are configured to drive the corresponding blue light diodes;
an insulating layer on a side of the plurality of driving circuits facing away from the first base substrate; where the insulating layer is provided with a plurality of grooves on a side facing away from the first base substrate; the reflective structures are on inner surfaces of the grooves, the quantum dot structures fill up corresponding grooves;
an encapsulation layer on a side of the insulating layer facing away from the quantum dot structures;
a plurality of groups of bonding pins on a side of the encapsulation layer facing away from the first base substrate; where each group of bonding pins is bound to one blue light diode, the bonding pins include anode pins and cathode pins, the anode pins are electrically connected with the driving circuits, and the cathode pins are electrically connected with a common electrode.

In some embodiments, the display panel further includes: a second substrate, where the second substrate and the first substrate are arranged in a box alignment manner, and the second substrate is bonded to the first substrate by a transparent adhesive;
the second substrate includes a second base substrate and a plurality of groups of color filters, the plurality of groups of color filters are on one surface of the second base substrate; each group of color filters includes a red color filter and a green color filter, the red color filter corresponds to a quantum dot structure emitting red light, and the green color filter corresponds to a quantum dot structure emitting green light.

In some embodiments, the each group of color filters further includes a blue color filter or a transparent resin, the transparent resin is configured to allow blue light emitted from the blue light diode to pass through and to be reflected by a corresponding reflective structure and then ejected from the second base substrate.

In some embodiments, every three reflective structures form a group of reflective structures;
in each group of reflective structures, two reflective structures correspond to a quantum dot structure emitting red light and a quantum dot structure emitting green light, respectively, and a remaining reflective structure corresponds to a transparent structure, the transparent structure fills up a groove corresponding to the remaining reflective structure.

In some embodiments, a longitudinal section pattern of the groove is an inverted isosceles trapezoid or arc shape.

In some embodiments, the blue light diodes are normal blue light diodes.

In some embodiments, the second substrate further includes:
a distributed Bragg reflector layer on a side of the second base substrate close to the plurality of blue light diodes;
where the distributed Bragg reflector layer is provided with through-holes at positions corresponding to the reflective structures not corresponding to the quantum dot structures, orthographic projections of the reflective structures not corresponding to the quantum dot structures on the distributed Bragg reflector layer are within the through-holes;
a planarization layer, filled in the through-holes.

In some embodiments, the blue light diodes are distributed Bragg reflector blue light diodes.

In a second aspect, embodiments of the present disclosure provide a display device including the display panel described in the first aspect.

### BRIEF DESCRIPTION OF FIGURES

FIG. 1 is a schematic diagram of a structure of a display panel provided by an embodiment of the present disclosure.

FIG. 2 is a schematic diagram of the structure of a normal blue light diode with a flip structure.

FIG. 3 is a top view of a normal blue light diode with a flip structure.

FIG. 4 is a schematic diagram of the structure of a vertically structured normal blue light diode.

FIG. 5 is a top view of a vertically structured normal blue light diode.

FIG. 6 is a schematic diagram of DBR blue light diode with a flip structure.

FIG. 7 is a top view of a DBR blue light diode with a flip structure.

FIG. 8 is a schematic diagram of DBR blue light diode with a vertical structure.

FIG. 9 is a schematic diagram of the transmittance of the DBR blue light diode.

FIG. 10 is a comparison of the light efficiency between the reflective structure disclosed in embodiments of the present disclosure and the transmission structure in related technologies.

FIG. 11 is a schematic diagram of the structure of another display panel provided by embodiments of the present disclosure.

FIG. 12 is a first base substrate provided by embodiments of the present disclosure.

FIG. 13 is a schematic diagram of the structure of a first substrate provided by an embodiment of the present disclosure.

FIG. 14 is a schematic diagram of the structure of another first substrate provided by embodiments of the present disclosure.

FIG. 15 is a schematic diagram of fabricating a first substrate provided by embodiments of the present disclosure.

FIG. 16 is a schematic diagram of the spacing of the blue light diode and the grooves provided by embodiments of the present disclosure.

FIG. 17 is a schematic structural diagram of another first base substrate provided by embodiments of the present disclosure.

FIG. 18 is a schematic diagram of the structure of a first substrate provided by an embodiment of the present disclosure.

FIG. 19 is a schematic structural diagram of another first base substrate provided by embodiments of the present disclosure.

FIG. 20 is a schematic diagram of the structure of another first substrate provided by embodiments of the present disclosure.

FIG. 21 is a schematic diagram of a structure of a first substrate and a second substrate constituting a backlight source provided by embodiments of the present disclosure.

FIG. 22 is a schematic diagram of the structure of a second substrate provided by embodiments of the present disclosure.

FIG. 23 is a schematic diagram of the fabrication of a second substrate provided by embodiments of the present disclosure.

FIG. 24 is a schematic diagram of the structure of another second substrate provided by embodiments of the present disclosure.

FIG. 25 is a schematic diagram of the structure of another display panel provided by embodiments of the present disclosure.

FIGS. 26 and 27 are schematic structural diagrams of another second substrate provided by embodiments of the present disclosure.

FIG. 28 is a schematic diagram of the structure of another display panel provided by embodiments of the present disclosure.

FIG. 29 is a schematic diagram of the structure of another display panel provided by an embodiment of the present disclosure.

FIG. 30 is a schematic diagram of the structure of another first substrate provided by embodiments of the present disclosure.

FIG. 31 is a schematic diagram of the structure of another display panel provided by embodiments of the present disclosure.

FIG. 32 is a schematic diagram of the structure of another display panel provided by embodiments of the present disclosure.

FIG. 33 is a schematic diagram of the structure of another second substrate provided by embodiments of the present disclosure.

### DETAILED DESCRIPTION

Embodiments of the present disclosure provide a display panel and a display device for solving a technical problem of low blue light absorption rate of a quantum dot-based display product existing in the related art.

In order to make the above purposes, features and advantages of the present disclosure more apparent and understandable, the present disclosure will be further described below in connection with the accompanying drawings and embodiments. However, the exemplary embodiments can be implemented in a variety of forms and should not be construed as being limited to embodiments set forth herein; rather, the provision of these embodiments makes the present disclosure more comprehensive and complete and conveys the idea of the exemplary embodiments comprehensively to those skilled in the art. The same appendix markings in the drawings denote the same or similar structures, and thus repetitive descriptions of them will be omitted. Words used in the present disclosure to express position and direction are used in the accompanying drawings as an example, but changes may be made as necessary, and such changes are included in the scope of protection of the present disclosure. The accompanying drawings in the present disclosure are only used to illustrate the relative position relationship does not represent the true proportion.

It should be noted that specific details are set forth in the following description to facilitate a full understanding of the present disclosure. However, the present disclosure is capable of being implemented in a variety of other ways different from those described herein, and those skilled in the art may similarly generalize the present disclosure without violating the content of the present disclosure. The present disclosure is therefore not limited by the specific embodiments disclosed below. The subsequent description of the specification for the implementation of the present disclosure of the better way of implementation, but the description is to illustrate the general principles of the present disclosure for the purpose of the purpose of the present disclosure, is not intended to limit the scope of the present disclosure. The scope of protection of the present disclosure shall be as defined in the appended claims.

A display panel and a display device provided by embodiments of the present disclosure are described below in connection with the accompanying drawings.

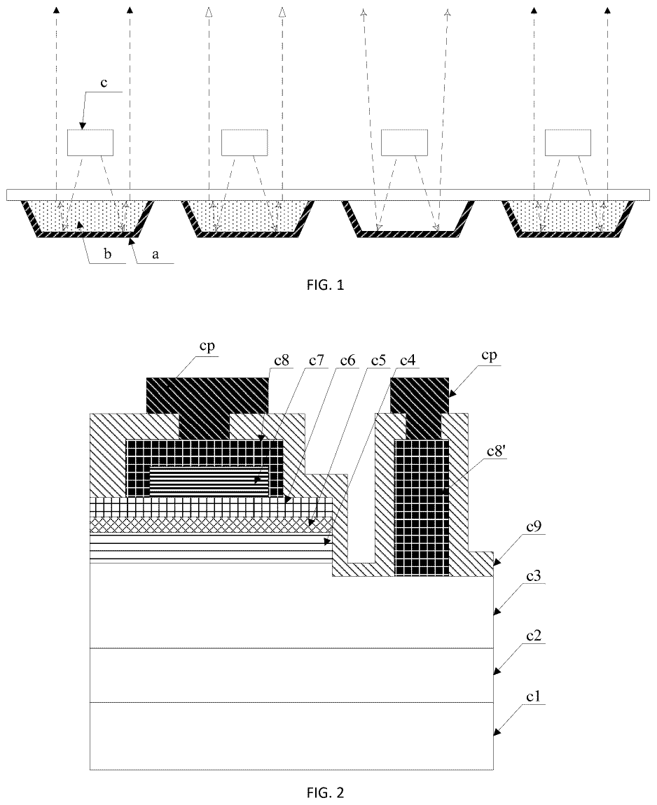

Referring to FIG. 1 for a schematic diagram of a structure of a display panel provided by an embodiment of the present disclosure, the display panel includes:
a plurality of reflective structures a;
a plurality of quantum dot structures b on a side of the plurality of reflective structures a; and
a plurality of blue light diodes c on a side of the plurality of quantum dot structures b facing away from the plurality of reflective structures a, where the blue light diodes c emit blue light at least towards corresponding reflective structures a.

The reflection structure a can be made of metal materials.

Blue light diode c can be a normal blue light diode or a distributed Bragg reflector (DBR) blue light diode.

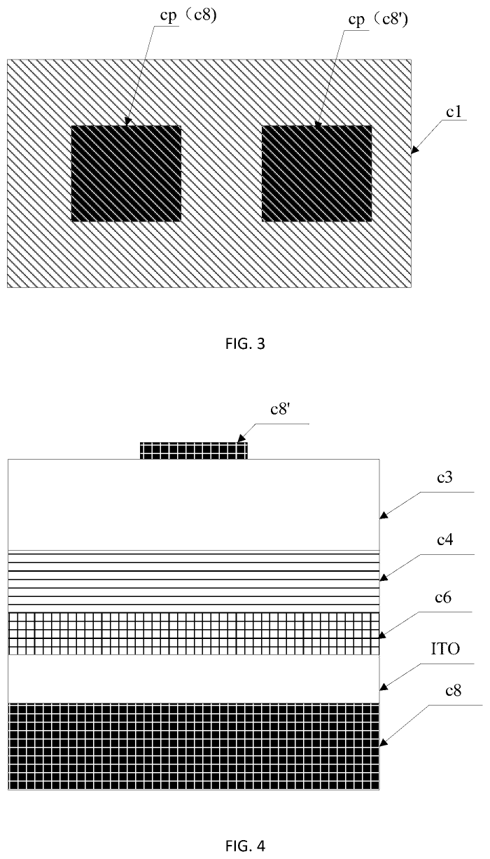

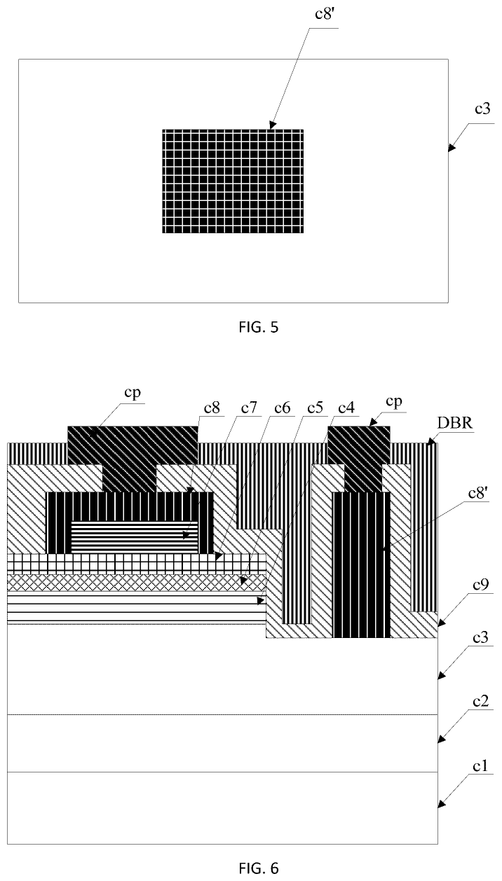

The normal blue light diode can emit light on one side, at this time, the normal blue light diode emits light towards the reflection structure a in the display panel, and the normal blue light diode can also emit light on both sides, that is, the normal blue light diode emits light towards the reflection structure a and emits light towards a direction facing away from the reflection structure a. Referring to FIG. 2 to FIG. 5. FIG. 2 is a schematic diagram of the structure of a normal blue light diode with a flip structure. FIG. 3 is a top view of a normal blue light diode with a flip structure. FIG. 4 is a schematic diagram of the structure of a vertically structured normal blue light diode. FIG. 5 is a top view of a vertically structured normal blue light diode.

As shown in FIG. 2, a normal blue light diode with a flip structure includes: a third base substrate c1, a buffer layer c2 located at one side of the third base substrate c1, an N-type gallium nitride c3 on a side of the buffer layer c2 facing away from the third base substrate c1, a multi quantum wells c4 on a side of the N-type gallium nitride c3 facing away from the third base substrate c1, an electronic barrier layer c5 on a side of the multiple quantum wells facing away from the third base substrate c1, an P-type gallium nitride c6 on a side of the electronic barrier layer c5 facing away from the third base substrate c1, the current expansion layer c7 on a side of the P-type gallium nitride c6 facing away from the third base substrate, the anode c8 covering the current expansion layer c7, the cathode c8′ on a side of the N-type gallium nitride c3 facing away from the third base substrate c1, where the cathode c8′, the multi quantum wells c4, the electronic barrier layer c5, the P-type gallium nitride c6, the current expansion layer c7 and the anode c8 are all arranged at intervals. The normal blue light diode with a flip structure further includes: the insulation layer c9 on a side of the anode c8 and the cathode c8′ facing away from the third base substrate c1, and the two pins cp on a side of the insulation layer c9 facing away from the third base substrate c1, where the two pins are respectively connected with the anode c8 and the cathode c8′. Two pins of a normal blue light diode with a flip structure are located on the same side, as shown in FIG. 3. The third base substrate can be a silicon substrate or a sapphire substrate.

As shown in FIG. 4, the normal blue light diode with vertical structure includes: an anode c8, an indium tin oxide layer ITO on a side of the anode c8, an P-type gallium nitride c6 on a side of the indium tin oxide layer ITO facing away from the anode c8, multi quantum wells c4 on a side of the P-type gallium nitride c6 facing away from the anode c8, an N-type gallium nitride c3 on a side of the multi quantum wells c4 facing away from the anode c8, a cathode c8′ on a side of the N-type gallium nitride c3 facing away from the anode c8. The anode c8 and the cathode c8′ of the normal blue light diode with vertical structure are located at different sides, as shown in FIG. 5.

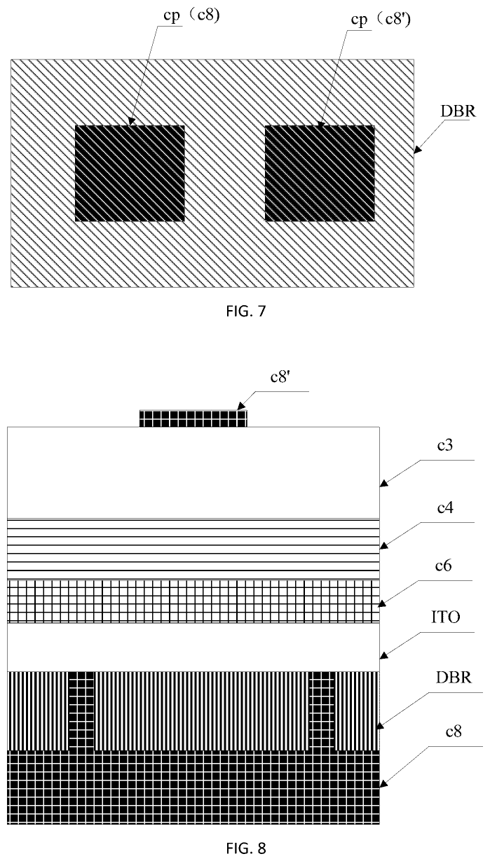

The DBR blue light diode emits light on one side, that is, the DBR blue light diode emits light toward the reflection structure a. As shown in FIG. 6 to FIG. 8, FIG. 6 is a schematic diagram of DBR blue light diode with a flip structure, FIG. 7 is a top view of a DBR blue light diode with a flip structure, FIG. 8 is a schematic diagram of DBR blue light diode with a vertical structure.

As shown in FIG. 6, when the DBR blue light diode adopts the flip structure, compared with the normal blue light diode adopting the island structure, the DBR blue light diode is provided with a distributed Bragg reflector DBR on a side of the insulation layer c9 facing away from the third base substrate c3. FIG. 7 is the top view corresponding to FIG. 6.

As shown in FIG. 8, when the DBR blue light diode adopts a vertical structure, compared with the normal blue light diode with a vertical structure, the DBR blue light diode is provided with a distributed Bragg reflector DBR between the anode c8 and the indium tin oxide layer ITO. The corresponding top view of FIG. 8 can be seen in FIG. 5.

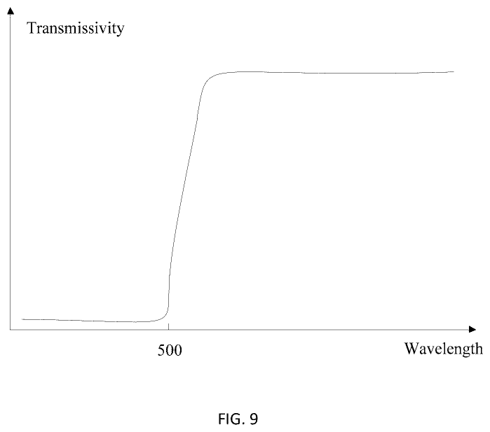

FIG. 9 is a schematic diagram of the transmittance of the DBR blue light diode, where the vertical axis is the transmittance and the horizontal axis is the wavelength. Since the DBR blue light diode is provided with a distributed Bragg reflector DBR layer, the light emitted from the quantum dot structure b emitting red light and the quantum dot structure b emitting green light can be transmitted to the reverse side of the light emitting side of the DBR blue light diode, so that the DBR blue light diode will not block the red light and green light, thereby improving the opening rate and light flux of the corresponding sub-pixel and improving the display effect.

In embodiments provided by the present disclosure, by using the DBR blue light diode as the blue light diode c corresponding to the quantum dot structure b, the light emitted by the corresponding quantum dot structure b can be transmitted through the corresponding DBR blue light diode, which is equivalent to increasing the opening rate of the corresponding sub-pixel, thus increasing the excess light flux.

In some embodiments, the blue light diode c corresponding to the quantum dot structure b is a DBR blue light diode, and the blue light diode c not corresponding to the quantum dot structure b is a double-sided normal blue light diode, which can improve the opening ratio of each pixel in the display panel and improve the display effect.

As shown in FIG. 1, the blue light diode c emits blue light at least towards the reflection structure a, so that the blue light emitted by the blue light diode c to the reflection structure a is absorbed by the quantum dot structure b arranged between the reflection structure a and the blue light diode c before reaching the reflection structure a, and the part of blue light not absorbed by the quantum dot structure b can be absorbed by the quantum dot structure b after being reflected by the reflection structure a. Thus, compared with the quantum dot with transmission structure in the related art, the quantum dot has higher blue light absorption efficiency, and can stimulate the quantum dot structure b to emit more light.

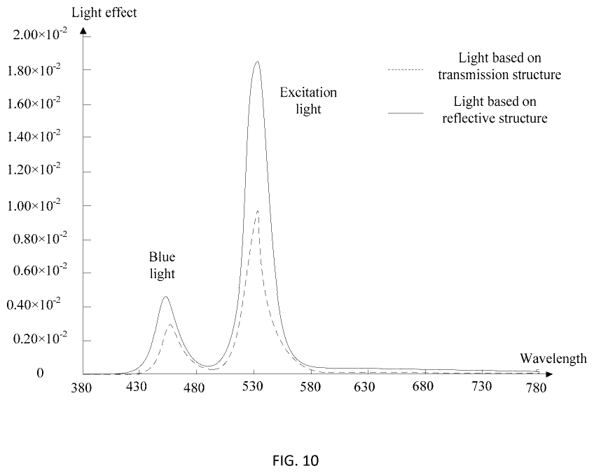

FIG. 10 is a comparison of the light efficiency between the reflective structure disclosed in embodiments of the present disclosure and the transmission structure in related technologies. Where, the horizontal axis is the wavelength and the vertical axis is the light effect. It can be seen from FIG. 10 that the light effect of the reflection structure a of the present disclosure is significantly improved compared with the light effect of the transmission structure.

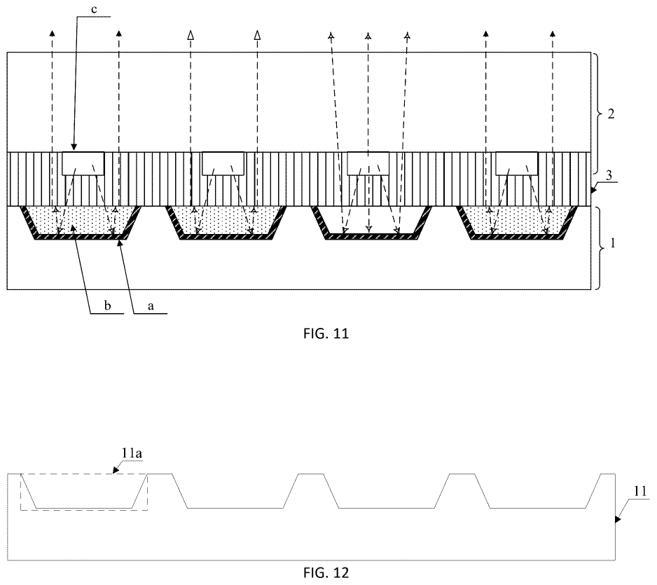

In embodiments provided by the present disclosure, by setting the reflection structures a, and setting the quantum dot structures b between the blue light diodes c and the reflection structures a, the blue light diodes c emit blue light toward the reflection structure a, so that the blue light not absorbed by the quantum dot structures b at one time can be reflected by the reflection structures a, and the quantum dot structure b can absorb the blue light again. Furthermore, it can effectively improve the efficiency of quantum dots to absorb blue light, and improve the luminous efficiency of quantum dot structures b. FIG. 11 is a schematic diagram of the structure of another display panel provided by embodiments of the present disclosure, the display panel includes:
a first substrate 1 and a second substrate 2 arranged in a box alignment manner, where the first substrate 1 is bonded to the second substrate 2 by means of a transparent adhesive 3;
the plurality of reflection structures a and the plurality of quantum dot structures b are arranged on the first substrate 1;
the plurality of blue light diodes c are arranged on the second substrate 2.

In embodiments provided by the present disclosure, by setting the blue light diodes c on the second substrate 2, and setting the reflection structures a and the quantum dot structures b on the first substrate 1, it is convenient to bond the blue light diodes c on the second substrate 2 without affecting the first substrate 1. The second substrate 2 bound with the blue light diodes c is bonded with the first substrate 1 containing the reflection structures a and the quantum dot structures b through transparent adhesive 3, it is convenient to make the blue light emitted by the blue light diodes c pass through the quantum dot structures b again to improve the absorption of blue light.

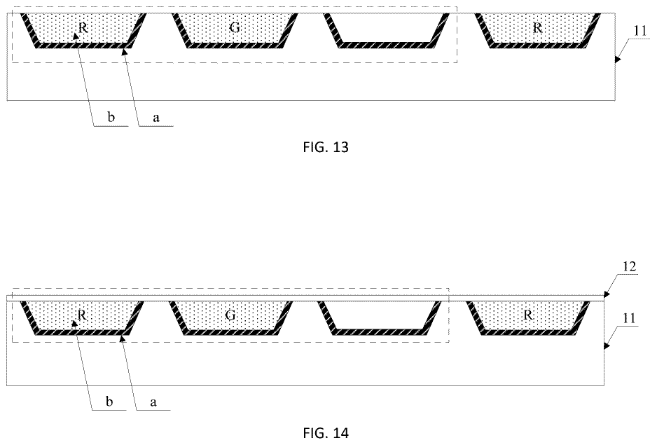

Referring to FIG. 12 and FIG. 13, FIG. 12 is a first base substrate provided by embodiments of the present disclosure, FIG. 13 is a schematic diagram of the structure of a first substrate provided by an embodiment of the present disclosure, the first substrate 1 further includes:
a first base substrate 11; where the first base substrate 11 may be a glass substrate, or a substrate of other materials, it is not limited here;
as shown in FIG. 12, the first base substrate 11 is provided with a plurality of grooves 11a on a side facing the second substrate 2;
as shown in FIG. 13, the reflection structures a are on the inner surfaces of the grooves 11a, and the quantum dot structures b fill the corresponding grooves 11a.

In embodiments provided by the present disclosure, by setting the plurality of grooves 11a on the surface of the first base substrate 11 towards the second substrate 2, and setting the reflection structures a on the inner surfaces of the grooves 11a, and then filling the corresponding grooves 11a with the quantum dot structures b, the light emitted by the quantum dot structures b corresponding to different grooves 11a can be prevented from interfering with each other to improve the display effect, and the thickness of the first substrate 1 can also be reduced.

FIG. 14 is a schematic diagram of the structure of another first substrate provided by embodiments of the present disclosure. The first substrate 1 further includes an encapsulation layer 12, which is on a side of the quantum dot structures b facing away from the first base substrate 11.

By setting the encapsulation layer 12 on the side of the quantum dot structures b facing away from the first base substrate 11, the quantum dot structures b can be encapsulated in the corresponding grooves 11a, and the quantum dot structures b can be protected.

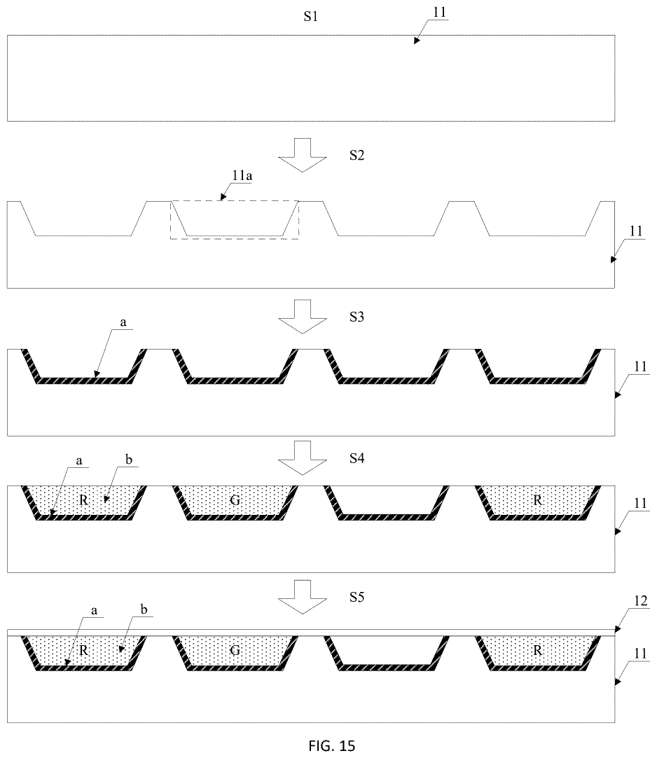

FIG. 15 is a schematic diagram of fabricating a first substrate provided by embodiments of the present disclosure.

S1: provide the first base substrate 11;

S2: etch a plurality of grooves 11a on a side of the first base substrate 11;

S3: deposit metal layer on the surfaces of grooves 11a to form reflective structures a;

S4: print the quantum dots on the side of the reflection structures a facing away from the first base substrate 11 to form the quantum dot structures b, so that the quantum dot structures b fill the corresponding grooves 11a.

S5: form an encapsulation layer 12 on the side of the quantum dot structures b facing away from the first base substrate 11.

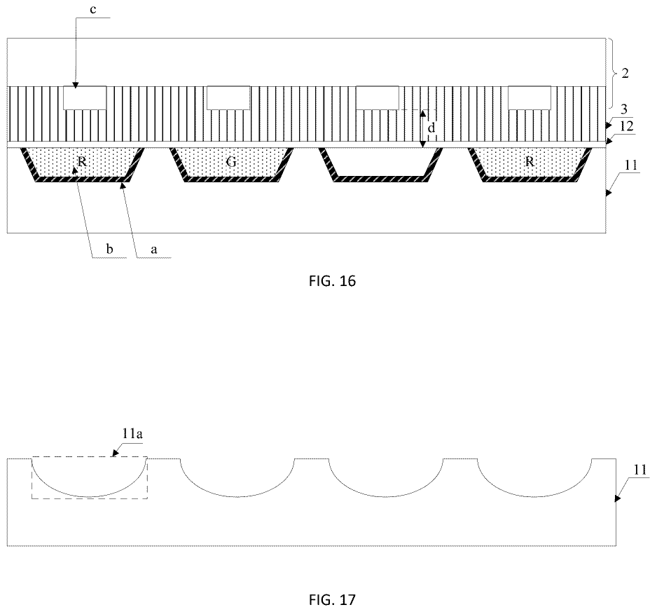

FIG. 16 is a schematic diagram of the spacing of the blue light diode and the grooves provided by embodiments of the present disclosure.

The distance d between blue light diode c and groove 11a is greater than or equal to 0 um.

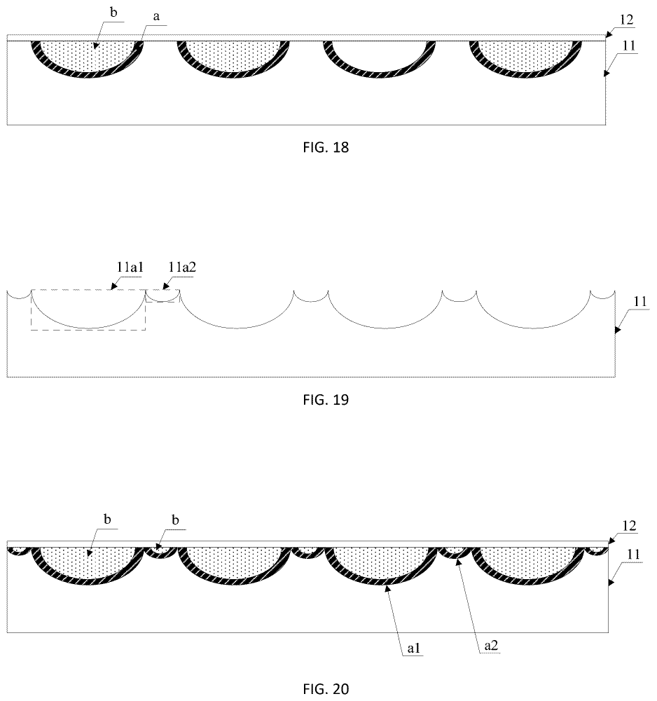

Please continue to refer to FIG. 12; a longitudinal section pattern of the groove 11a can be an inverted isosceles trapezoid or an arc as shown in FIG. 17. FIG. 17 is a schematic structural diagram of another first base substrate provided by embodiments of the present disclosure. The structural diagram of the first substrate 1 corresponding to the first base substrate 11 shown in FIG. 17 is shown in FIG. 18.

FIG. 19 is a schematic structural diagram of another first base substrate provided by embodiments of the present disclosure. The grooves 11a in the first base substrate 11 include:
the plurality of primary grooves 11a1 and at least one secondary groove 11a2 are arranged continuously in the first direction X; one secondary groove 11a2 can be arranged between two adjacent primary grooves 11a1, and two or more secondary grooves 11a2 can also be arranged, which is not limited here.

FIG. 20 is a schematic diagram of the structure of another first substrate provided by embodiments of the present disclosure. The reflection structures a in the first substrate 1 include:
the primary reflective structures a1 and at least one secondary reflective structure a2 arranged continuously in the first direction X; the primary reflective structures a1 are on the inner surfaces of the primary grooves 11a1, and the secondary reflective structures a2 are on the inner surfaces of the secondary grooves 11a2;
the primary reflective structure a1 corresponds to one blue light diode c, and at least one secondary reflective structure a2 is located between two adjacent primary reflective structures a1; The longitudinal cross-sectional area of the secondary reflective structure a2 is smaller than a longitudinal cross-sectional area of the primary reflective structure a1. As shown in FIG. 20, one secondary reflection structure a2 can be arranged between two adjacent primary reflective structures a1, or two or more secondary reflection structures a2 can be arranged, depending on the number of secondary grooves 11a2.

The quantum dot structures b include the mixture material of the quantum dots emitting red light and the quantum dots emitting green light.

In embodiments provided by the present disclosure, at least one secondary groove 11a2 is arranged between adjacent primary grooves 11a1, and a primary reflective structure a1 corresponding to blue light diode c is formed on the surface of the primary groove 11a1, and a secondary reflective structure a2 is formed on the surface of the secondary groove 11a2. The quantum dot structures b containing the quantum dots emitting red light and the quantum dots emitting blue light are formed on the side of the primary reflective structure a1 and the secondary reflective structure a2 towards the blue light diodes c, so that after the blue light emitted by the blue light diode c excites the quantum dot structure b, red light and green light can be emitted, and mixed with the unabsorbed blue light to form white light. Thus, the combination of the first substrate 1 and the second substrate 2 can be used as a direct-lit backlight of the display panel. As shown in FIG. 21, FIG. 21 is a schematic diagram of a structure of a first substrate and a second substrate constituting a backlight source provided by embodiments of the present disclosure.

As shown in FIG. 20, when the longitudinal section of groove 11a is arc shaped, the longitudinal sections of the primary reflective structure a1 and the secondary reflective structure a2 formed on the surface of groove 11a are also arc shaped. When the blue light emitted by the blue light diode c reaches the primary reflective structure a1 and the secondary reflective structure a2, the blue light can be reflected in all directions to avoid specular reflection. Further, the light output uniformity of the backlight source composed of the first substrate 1 and the second substrate 2 can be improved.

When the combination of the first substrate 1 and the second substrate 2 is used for display, please continue to refer to FIG. 13; and every three reflection structures a are a group (shown in the dotted box in FIG. 13).

In each group of reflective structures a, the two reflection structures a correspond to the quantum dot structure b emitting red light and the quantum dot structure b emitting green light respectively, the remaining reflection structure a corresponds to the transparent structure, and the transparent structure fills the groove 11a corresponding to the remaining reflection structure a.

Every three reflective structures a corresponds to a red sub-pixel(R), a green sub-pixel (G), and a blue sub-pixel (B). The corresponding quantum dot structure b of the red sub-pixel emits red light after being excited by blue light, and the quantum dot structure b of the green sub-pixel emits green light after being excited by blue light. The corresponding groove 11a of the reflective structure a of the blue sub-pixel is filled with a transparent structure. The blue light emitted by the blue light diode c passes through the transparent structure and is reflected by the reflection structure a, and then passes through the transparent structure again to emit to the second substrate 2.

In embodiments provided by the present disclosure, by setting every three reflection structures a as a group, and making two reflection structures a in each group of reflection structures a correspond to the quantum dot structure b emitting red light and the quantum dot structure b emitting green light respectively, the remaining reflection structure a corresponds to the transparent structure, and the transparent structure fills the groove 11a corresponding to the remaining reflection structure a, the sub pixels displaying different colors in the display panel can be formed.

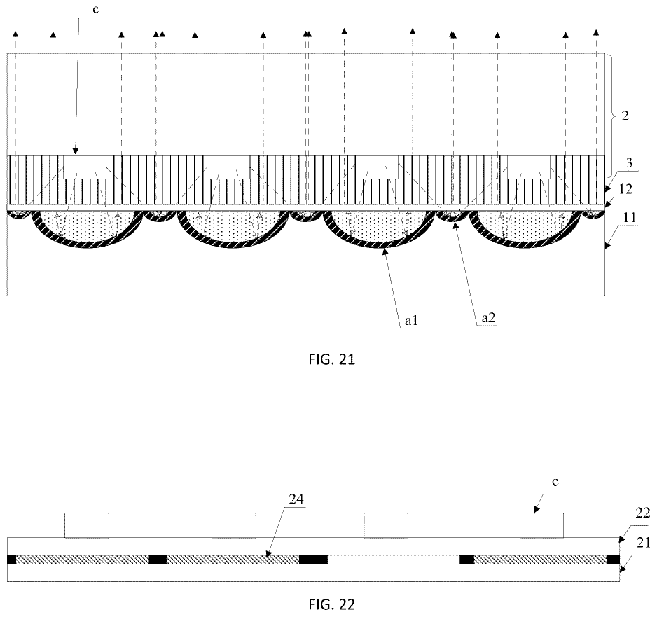

Referring to FIG. 22, FIG. 22 is a schematic diagram of the structure of a second substrate provided by embodiments of the present disclosure. The second substrate 2 further includes:
a second base substrate 21;
a plurality of groups of color filters 24 on a surface of the second base substrate 21; each group of color filters 24 includes a red color filter 24 and a green color filter 24; the red color filter 24 corresponds to the quantum dot structure b emitting red light, and the green color filter 24 corresponds to the quantum dot structure b emitting green light. The plurality of groups of color filters 24 can be arranged on the surface of the second base substrate 21 close to the blue light diode c, or on the surface of the second base substrate 21 facing away from the blue light diode c. There is also a driving circuit layer 22 between the film where the blue light diodes c are located and the film where the color filters 24 are located.

The red color filter 24 corresponds to the quantum dot structure b emitting red light, and the red color filter 24 only allows red light to pass through, so even if the blue light emitted by the blue light diode c corresponding to the quantum dot structure b emitting red light is not fully absorbed, it can also be filtered through the red color filter 24. The green color filter 24 corresponds to the quantum dot structure b that emits green light, and the green color filter 24 only allows green light to pass through. Therefore, even if the blue light emitted by the blue light diode c corresponding to the quantum dot structure b that emits green light is not fully absorbed, it can also be filtered through the green color filter 24, which can prevent cross color and improve the display effect.

Since the blue light diode c is used, there is no color mixing problem for the corresponding blue sub-pixel. Therefore, in the second substrate 2, the sub-pixel corresponding to the reflection structure a without the quantum dot structure b can be arranged without the blue color filter 24 or can be arranged with the blue color filter 24. When the blue color filter 24 is not arranged, transparent resin can be arranged at the corresponding position, so that the blue light emitted by the blue light diode c can not only pass through and be reflected by the reflection structure a from the side facing away from the first substrate 1, but also keep the film layer of multiple color filters 24 flat.

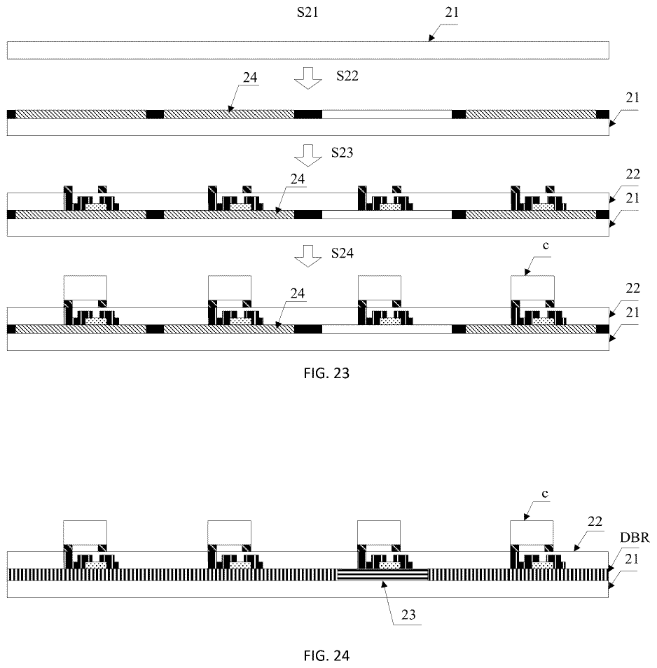

As shown in FIG. 23, FIG. 23 is a schematic diagram of the fabrication of a second substrate provided by embodiments of the present disclosure.

S21: provide the second base substrate 21.

S22: form a plurality of color filters 24 on one side of the second base substrate 21.

S23: form a driving circuit layer 22 on the side of the plurality of color filters 24 facing away from the second base substrate 21; where pins bound to the blue light diode c can be arranged on a side of the driving circuit layer 22 facing away from the second base substrate 21.

S24: bond the blue light diode c and the pins which are arranged on a side of the driving circuit layer 22 facing away from the second base substrate 21.

Since the normal blue light diode is located at the light emitting side of the display panel, the light emitted by the quantum dot structure b will be partially blocked, thereby reducing the opening ratio of the corresponding sub-pixel of the quantum dot structure b.

Refer to FIG. 24 for a schematic diagram of the structure of another second substrate provided by embodiments of the present disclosure.

The second substrate 2 further includes:
a distributed Bragg reflector (DBR) layer on the side of the second base substrate 21 close to a plurality of blue light diodes c; where the distributed Bragg reflector DBR layer is provides with through-holes at positions with the reflective structures a not corresponding to the quantum dot structures b, orthographic projections of the reflective structures a not corresponding to the quantum dot structures b on the distributed Bragg reflector DBR layer are within the through-holes;
a planarization layer 23, filled in the through-holes.

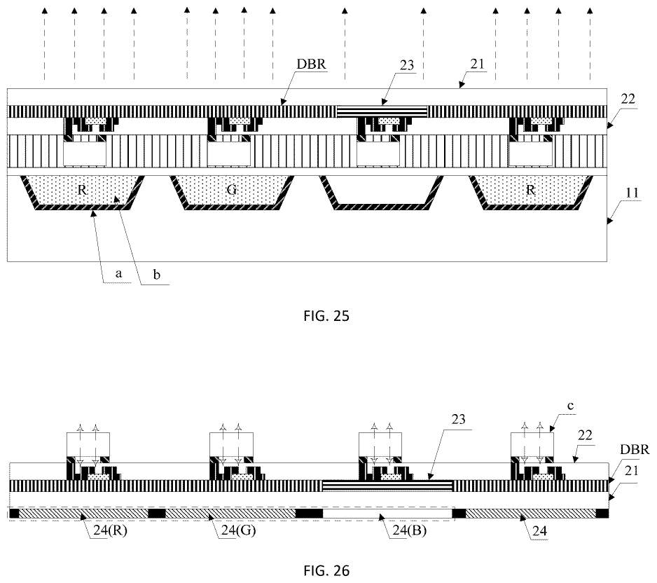

Refer to FIG. 25 for the structural diagram of another display panel provided by embodiments of the present disclosure. The second substrate 2 in FIG. 25 is the second substrate 2 shown in FIG. 24. Since the optical property of the distributed Bragg reflector DBR is to reflect blue light while transmitting red and green light, the opening area of the distributed Bragg reflector DBR layer and the blue pixel (that is, the reflection structure a that does not correspond to the quantum dot structure b) does not overlap. It is necessary to set a through-hole and fill the transparent planarization layer 23 in the through-hole.

Since the distributed Bragg reflector DBR layer covers the corresponding sub-pixel of the quantum dot structure b, the light emitted by the quantum dot structures b emitting red light and the quantum dot structures b emitting green light can be transmitted to the rear end of the normal blue light diode, so that the normal blue light diode will not block the red light and green light. Furthermore, since the distributed Bragg reflector DBR layer can reflect blue light, even if the normal blue light diode is two-sided, it can also reflect the received blue light to the quantum dot structure b through the distributed Bragg reflector DBR layer, so as to stimulate the quantum dot to emit light, which can not only effectively improve the sub-pixel opening rate, but also further improve the light throughput and improve the display effect.

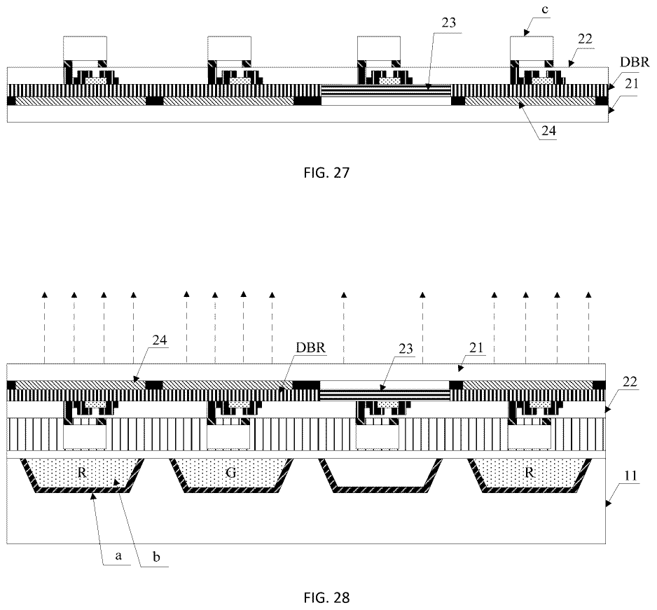

Refer to FIG. 26 and FIG. 27 for the structural diagram of another second substrate provided by embodiments of the present disclosure. As shown in FIG. 26, multiple groups of color filters 24 can be arranged on the surface of the second base substrate 21 facing away from the blue light diode c. Multiple groups of color filters 24 can also be arranged on the surface of the second base substrate 21 close to the blue light diode c, as shown in FIG. 27.

It should be understood that, in order to increase the excess light flux, in FIGS. 26 and 27, normal double-sided light-emitting blue light diodes are used, and distributed Bragg reflector DBR layer is arranged. If the blue light diode c is a distributed Bragg reflector blue light diode, it is unnecessary to set the distributed Bragg reflection layer DBR. Refer to FIG. 28 for the structural diagram of another display panel provided by embodiments of the present disclosure. The second substrate in FIG. 28 is the second substrate in FIG. 27.

The red color filter 24 corresponds to the quantum dot structure b emitting red light, and the red color filter 24 only allows red light to pass through, so even if the blue light emitted by the blue light diode c corresponding to the quantum dot structure b emitting red light is not fully absorbed, it can also be filtered through the red color filter 24. The green color filter 24 corresponds to the quantum dot structure b that emits green light, and the green color filter 24 only allows green light to pass through. Therefore, even if the blue light emitted by the blue light diode c that corresponds to the quantum dot structure b that emits green light is not fully absorbed, it can also be filtered through the green color filter 24, thus preventing cross color and further improving the display effect.

Since the blue light diode c is used, there is no color mixing problem for the corresponding blue sub-pixel. Therefore, in the second substrate 2, the sub-pixel corresponding to the reflection structure a without the quantum dot structure b can be arranged without the blue color filter 24 or can be arranged with the blue color filter 24. When the blue color filter 24 is not arranged, transparent resin can be set at the corresponding position, so that the blue light emitted by the blue light diode c can not only pass through and be reflected by the reflection structure a, and exits from the side facing away from the first substrate 1, but also keep the film layer of multiple color filters 24 flat.

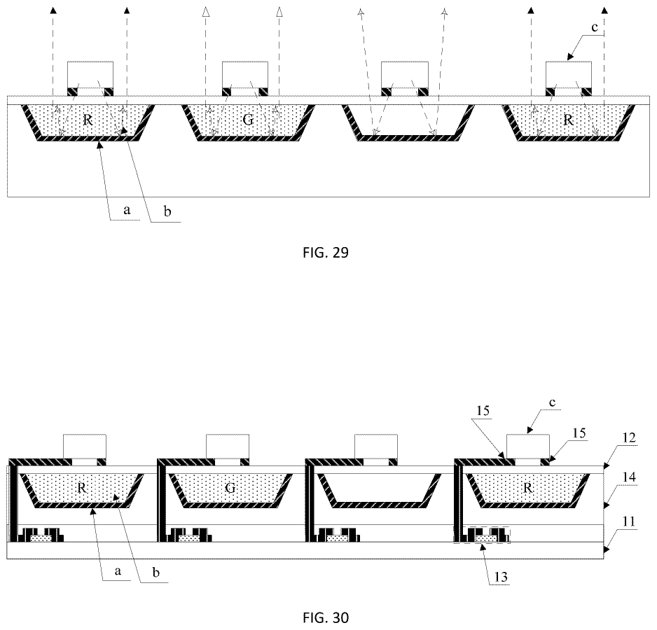

Referring to FIG. 29 for a schematic diagram of a structure of another display panel provided by embodiments of the present disclosure, the display panel includes:
a first substrate 1; the plurality of reflection structures a, a plurality of quantum dot structures b, and a plurality of blue light diodes c are all arranged on the first substrate 1.

In embodiments provided by the present disclosure, the alignment error between the blue light diodes c and the reflection structures a and the quantum dot structures b can be reduced by making the reflection structures a, the quantum dot structures b and the blue light diodes c on the same substrate.

Referring to FIG. 30 for a schematic structural diagram of another first substrate provided by embodiments of the present disclosure, the first substrate 1 further includes:
a first base substrate 11;
a plurality of driving circuits 13 on a side of the first base substrate 11; where the plurality of driving circuits 13 correspond one-to-one with the plurality of blue light diodes c, the driving circuits 13 are configured to drive the corresponding blue light diodes c;
an insulating layer 14 on a side of the plurality of driving circuits 13 facing away from the first base substrate 11; where the insulating layer 14 is provided with a plurality of grooves 11a on a side of the insulating layer 14 facing away from the first base substrate 11; the reflective structures a are on inner surfaces of the grooves 11a, the quantum dot structures b fill up corresponding grooves 11a;
an encapsulation layer 12 on a side of the insulating layer 14 facing away from the quantum dot structures b;
a plurality of groups of bonding pins 15 on a side of the encapsulation layer 12 facing away from the first base substrate 11; where each group of bonding pins 15 is bound to one blue light diode c, the bonding pins 15 include anode pins and cathode pins, the anode pin is electrically connected with the driving circuit 13, and the cathode pin is electrically connected with a common electrode.

In embodiments provided by the present disclosure, by setting the driving circuit 13 on the side of the reflection structure a facing away from the blue light diode c, the corresponding blue light diode c can be controlled by the driving circuit 13, and the opening rate of the corresponding sub-pixel can be improved by preventing the driving circuit 13 from blocking the opening of the corresponding sub-pixel.

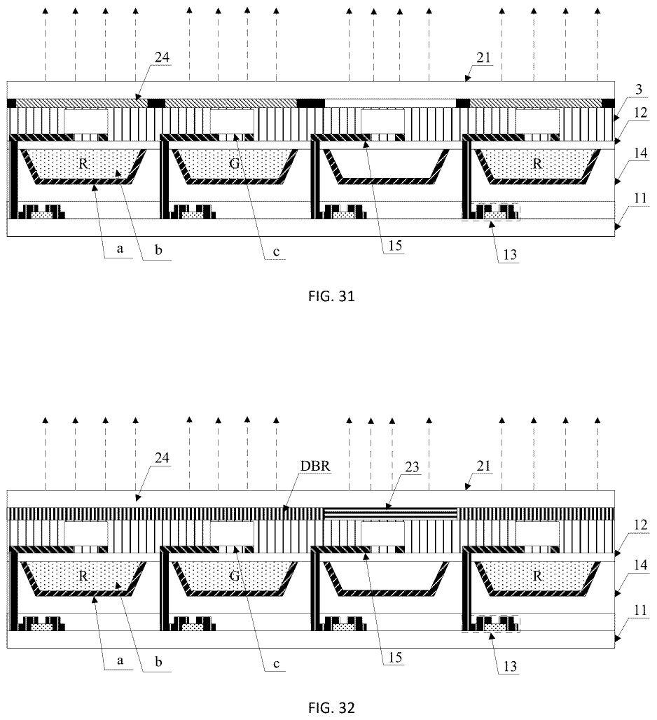

Refer to FIG. 31 for a schematic diagram of the structure of another display panel provided by embodiments of the present disclosure.

The display panel further includes a second substrate 2, where the second substrate 2 and the first substrate 1 are arranged in a box alignment manner, and the second substrate 2 is bonded to the first substrate 1 by means of a transparent adhesive;
the second substrate 2 includes a second base substrate 21 and a plurality of groups of color filters 24, the plurality of groups of color filters 24 are on one surface of the second base substrate 21; each group of color filters 24 includes a red color filter 24 and a green color filter 24, the red color filter 24 corresponds to a quantum dot structure b emitting red light, and the green color filter 24 corresponds to a quantum dot structure b emitting green light.

As shown in FIG. 31, the plurality of groups of color filters 24 may be provided on the surface of the second base substrate 21 facing the first substrate 1, or on the surface of the second base substrate 21 facing away from the first substrate 1.

At the position corresponding to the blue sub-pixel in the second substrate 2 (that is, the position where the multiple color filters 24 are in the film layer that does not correspond to the quantum dot structure b), the blue color filters 24 can be arranged or the blue color filters 24 cannot be arranged. If the blue color filters 24 in the corresponding position of the blue color filter 24 are not arranged, transparent resin can be arranged to fill the corresponding position. This not only allows the light emitted by the blue light diode c to pass through and be reflected by the corresponding reflective structure a before exiting from the second substrate 21, but also maintains the flatness of the film layer where multiple color filters 24 are located.

The blue light diode c shown in FIG. 31 can be a normal blue light diode or a distributed Bragg reflection (DBR) blue light diode.

When an normal blue light diode is used, the normal blue light diode can emit light on both sides, that is, it can emit light toward the side where reflection structure a is located, and it can also emit light toward the side where the second base substrate 21 is located. At this time, please refer to FIG. 32 for the structural diagram of another display panel provided by embodiments of the disclosure. The second substrate 2 in the display panel further includes:
a distributed Bragg reflector (DBR) layer on the side of the second base substrate 21 close to a plurality of blue light diodes c; where the distributed Bragg reflector DBR layer is provides with through-holes at positions with the reflective structures a not corresponding to the quantum dot structures b, orthographic projections of the reflective structures a not corresponding to the quantum dot structures b on the distributed Bragg reflector DBR layer are within the through-holes;
a planarization layer 23, filled in the through-holes.

In embodiments provided by the present disclosure, by setting a distributed Bragg reflector DBR layer on the side of the second base substrate 21 close to the blue light diode c, and setting through-holes at the positions of the distributed Bragg reflector DBR layer with the reflective structures a not corresponding to the quantum dot structures b, and filling the flat layer 23 in the through-holes, the distributed DBR can filter out the blue light that is not completely absorbed at the corresponding position of the quantum dot structure b, and allow the blue light at the position where the quantum dot structure b is not present to pass through the distributed Bragg reflector DBR layer, thereby improving the display effect.

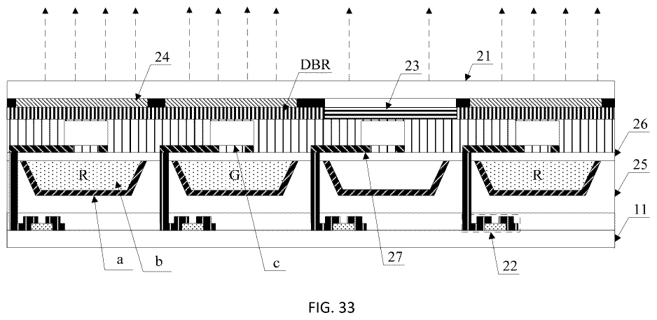

Refer to FIG. 33 for the structural diagram of another second substrate provided by embodiments of the present disclosure. The second substrate 2 can simultaneously include multiple groups of color filters 24 and distributed Bragg reflector DBR layer, which is located on the side of multiple groups of color filters 24 close to the blue light diode c. The display effect can be further improved by allowing the second substrate 2 to simultaneously include multiple groups of color filters 24 and distributed Bragg reflector DBR layer.

Based on the same inventive concept, embodiments of the present disclosure provide a display device; the display device includes the display panel as described above.

The display device can be a quantum dot monitor, quantum dot display, quantum dot TV and other display devices, as well as mobile devices such as cell phones, tablets, notebooks and other mobile devices.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the disclosure.

Evidently those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

1. A display panel, comprising:
a plurality of reflective structures;
a plurality of quantum dot structures on a side of the plurality of reflective structures; and
a plurality of blue light diodes on a side of the plurality of quantum dot structures facing away from the plurality of reflective structures;
wherein the blue light diodes emit blue light at least towards corresponding reflective structures.

2. The display panel according to claim 1, further comprising:
a first substrate and a second substrate arranged in a box alignment manner;
wherein the first substrate is bonded to the second substrate by a transparent adhesive;
the plurality of reflective structures and the plurality of quantum dot structures are on the first substrate;
the plurality of blue light diodes are on the second substrate.

3. The display panel according to claim 2, wherein the first substrate further comprises a first base substrate;
the first base substrate is provided with a plurality of grooves on a side facing the second substrate;
the reflective structures are on inner surfaces of the grooves, and the quantum dot structures fill up corresponding grooves.

4. The display panel according to claim 3, wherein the second substrate further comprises:
a second base substrate;
a plurality of groups of color filters on a surface of the second base substrate;
wherein each group of color filters comprises a red color filter and a green color filter; the red color filter corresponds to a quantum dot structure emitting red light, and the green color filter corresponds to a quantum dot structure emitting green light.

5. The display panel according to claim 3, wherein the grooves comprise:
a plurality of primary grooves arranged in a first direction and at least one secondary groove arranged between two adjacent primary grooves;
wherein the reflective structures comprise:
a plurality of primary reflective structures arranged in the first direction and at least one secondary reflective structure arranged between two adjacent primary reflective structures;
wherein the primary reflective structures are on inner surfaces of the primary grooves and the secondary reflective structure are on an inner surface of the secondary groove;
the primary reflective structure corresponds to one blue light diode; a longitudinal cross-sectional area of the secondary reflective structure is smaller than a longitudinal cross-sectional area of the primary reflective structure;
the quantum dot structures comprise a hybrid material of red light emitting quantum dots and green light emitting quantum dots.

6. The display panel according to claim 1, further comprising:
a first substrate;
wherein the plurality of reflective structures, the plurality of quantum dot structures, and the plurality of blue light diodes are on the first substrate.

7. The display panel according to claim 6, wherein the first substrate further comprises:
a first base substrate;
a plurality of driving circuits on a side of the first base substrate; wherein the plurality of driving circuits correspond one-to-one with the plurality of blue light diodes, the driving circuits are configured to drive the corresponding blue light diodes;
an insulating layer on a side of the plurality of driving circuits facing away from the first base substrate; wherein the insulating layer is provided with a plurality of grooves on a side facing away from the first base substrate; the reflective structures are on inner surfaces of the grooves, the quantum dot structures fill up corresponding grooves;
an encapsulation layer on a side of the insulating layer facing away from the quantum dot structures;
a plurality of groups of bonding pins on a side of the encapsulation layer facing away from the first base substrate; wherein each group of bonding pins is bound to one blue light diode, the bonding pins comprise anode pins and cathode pins, the anode pins are electrically connected with the driving circuits, and the cathode pins are electrically connected with a common electrode.

8. The display panel according to claim 7, further comprising:
a second substrate;
wherein the second substrate and the first substrate are arranged in a box alignment manner, and the second substrate is bonded to the first substrate by a transparent adhesive;
the second substrate comprises a second base substrate and a plurality of groups of color filters, the plurality of groups of color filters are on one surface of the second base substrate; each group of color filters comprises a red color filter and a green color filter, the red color filter corresponds to a quantum dot structure emitting red light, and the green color filter corresponds to a quantum dot structure emitting green light.

9. The display panel according to claim 4, wherein the each group of color filters further comprises a blue color filter or a transparent resin, the transparent resin is configured to allow blue light emitted from the blue light diode to pass through and to be reflected by a corresponding reflective structure and then ejected from the second base substrate.

10. The display panel according to claim 3, wherein every three reflective structures form a group of reflective structures;
in each group of reflective structures, two reflective structures correspond to a quantum dot structure emitting red light and a quantum dot structure emitting green light, respectively, and a remaining reflective structure corresponds to a transparent structure, the transparent structure fills up a groove corresponding to the remaining reflective structure.

11. The display panel according to claim 3, wherein a longitudinal section pattern of the groove is an inverted isosceles trapezoid or arc shape.

12. The display panel according to claim 2, wherein the blue light diodes are normal blue light diodes.

13. The display panel according to claim 12, wherein the second substrate further comprises:
a distributed Bragg reflector layer on a side of the second base substrate close to the plurality of blue light diodes;
wherein the distributed Bragg reflector layer is provided with through-holes at positions corresponding to reflective structures not corresponding to quantum dot structures, orthographic projections of the reflective structures not corresponding to the quantum dot structures on the distributed Bragg reflector layer are within the through-holes;
a planarization layer, filled in the through-holes.

14. The display panel according to claim 1, wherein the blue light diodes are distributed Bragg reflector blue light diodes.

15. A display device, comprising the display panel according to claim 1.

16. The display panel according to claim 8, wherein the each group of color filters further comprises a blue color filter or a transparent resin, the transparent resin is configured to allow blue light emitted from the blue light diode to pass through and to be reflected by a corresponding reflective structure and then ejected from the second base substrate.

17. The display panel according to claim 6, wherein every three reflective structures form a group of reflective structures;
in each group of reflective structures, two reflective structures correspond to a quantum dot structure emitting red light and a quantum dot structure emitting green light, respectively, and a remaining reflective structure corresponds to a transparent structure, the transparent structure fills up a groove corresponding to the remaining reflective structure.

18. The display panel according to claim 6, wherein a longitudinal section pattern of the groove is an inverted isosceles trapezoid or arc shape.

19. The display device according to claim 15, the display panel further comprises:
a first substrate and a second substrate arranged in a box alignment manner;
wherein the first substrate is bonded to the second substrate by a transparent adhesive;
the plurality of reflective structures and the plurality of quantum dot structures are on the first substrate;
the plurality of blue light diodes are on the second substrate.

20. The display device according to claim 19, wherein the first substrate further comprises a first base substrate;
the first base substrate is provided with a plurality of grooves on a side facing the second substrate;
the reflective structures are on inner surfaces of the grooves, and the quantum dot structures fill up corresponding grooves.
